(19) United States
(12) Patent Application Publication
(10) Pub. No.: US 2019/0131130 A1
(43) Pub. Date: May 2, 2019

(54) ETCHING METAL OXIDE SUBSTRATES USING ALE AND SELECTIVE DEPOSITION

(71) Applicant: Lam Research Corporation, Fremont, CA (US)

(72) Inventors: David Charles Smith, Lake Oswego, OR (US); Richard Wise, Los Gatos, CA (US); Arpan Mahorowala, West Linn, OR (US); Dennis M. Hausmann, Lake Oswego, OR (US)

(21) Appl. No.: 15/799,675

(22) Filed: Oct. 31, 2017

(51) Int. Cl. H01L 21/033; H01L 21/311; H01L 21/02; H01L 21/67; H01L 21/683; C23F 4/00; C23C 16/455; C23C 16/40; C23C 16/52

(52) U.S. Cl. CPC H01L 21/0337; H01L 21/31116; H01L 21/0228; H01L 21/02189; H01L 21/02178; H01L 21/02205; C23C 16/52; H01L 21/67069; H01L 21/6831; C23F 4/00; C23C 16/45525; C23C 16/40; H01L 21/67207

(57) ABSTRACT

Methods of and apparatuses for processing a metal oxide film are provided. Methods involve (a) exposing the metal oxide film to a boron halide reactant and igniting a first plasma with a first bias power to modify a surface of the metal oxide film, and (b) exposing the modified surface of the metal oxide film to a second plasma at a second bias power and for a duration sufficient to remove the modified surface without sputtering. Methods also involve (c) selectively depositing a metal oxide material on the metal oxide film to fill crevices within the metal oxide film.

### BACKGROUND

Patterning methods are critical to semiconductor processing. Extreme ultraviolet (EUV) lithography has been explored to extend lithographic technology beyond its optical limits and replace current photolithography methods to pattern small critical dimension features. Current EUV lithography methods result in poor edge roughness and weak patterns that may ultimately render the substrate useless.

### SUMMARY

Provided herein are methods and apparatuses for processing semiconductor substrates. One aspect involves a method of processing a metal oxide film by a combination of ALE and selective ALD to smoothen the metal oxide film. In a particular embodiment, the metal oxide film is a EUV patterned metal oxide film on a carbon-based substrate, and the ALE and ALD are selective to the carbon-containing material of the substrate so that the patterned metal oxide film may be smoothened without damaging the underlying substrate. The smoothened patterned metal oxide film may then be used as a mask to etch the underlying carbon-based substrate resulting in improved local critical dimensions (LCD) of the features etched in the substrate.

In some embodiments, the method involves processing a metal oxide film. The method comprises: (a) exposing the metal oxide film to a boron halide reactant and igniting a first plasma with a first bias power to modify a surface of the metal oxide film; (b) exposing the modified surface of the metal oxide film to a second plasma at a second bias power and for a duration sufficient to remove the modified surface without sputtering; and (c) selectively depositing a metal oxide material on the metal oxide film to fill crevices within the metal oxide film. The metal oxide film may be smoothened as a result. In certain embodiments, (a) and (b) comprise an atomic layer etch (ALE) process, and (c) comprises an atomic layer deposition (ALD) process. Moreover, the ALE and/or the ALD processes may be selective to carbon-containing materials positioned beneath the metal oxide film. Still further, the metal oxide film may be smoothened without damaging the carbon-containing materials.

In some embodiments, the smoothened metal oxide film is used as a mask to etch a carbon-based substrate positioned beneath the metal oxide film resulting in improved local critical dimensions (LCD) of the features etched in the carbon-based substrate.

In some embodiments, the boron halide is boron trichloride gas (BCl₃).

In some embodiments, the second plasma is generated from chlorine gas (Cl₂).

In some embodiments, the second plasma is generated from an argon-containing gas.

In some embodiments, the first plasma is generated using a plasma power between about 300 W and about 900 W. The first bias power may be 0V and applied for about 5 seconds.

In some embodiments, the metal oxide film is zirconium oxide (ZrO₂) film.

In some embodiments, the metal oxide film is aluminum oxide (Al₂O₃) film. The modified surface of the aluminum oxide (Al₂O₃) film may be exposed to the second plasma that is generated from an argon-containing gas.

In some embodiments, the metal oxide material is zirconium oxide (ZrO₂). The zirconium oxide (ZrO₂) may be deposited by ALD using thermal half reaction of a zirconium precursor selected from a group consisting of: a zirconium amide, a zirconium halide, or a zirconium alkoxide, and an oxygen-containing precursor selected from a group consisting of: water, alcohol, ozone, or oxygen gas. A 1 second dose of zirconium amide provided at partial pressure of 10 mTorr reacted with water may be sufficient to achieve a saturated thickness of 1 Å per ALD cycle.

In some embodiments, the temperature at which deposition is conducted is dependent on thermal stability of the zirconium source.

In some embodiments, the deposition of the zirconium oxide (ZrO₂) by ALD is selective relative to carbon-containing materials positioned beneath the metal oxide film, and further wherein the an oxygen-containing precursor does not oxidize the carbon-containing materials.

In some embodiments, the metal oxide material is aluminum oxide (Al₂O₃), which may be deposited by ALD using thermal half reaction of an aluminum precursor selected from a group consisting of: an aluminum amide, an aluminum halide, an aluminum alkoxide, or an aluminum alkyl, and an oxygen-containing precursor selected from a group consisting of: water, alcohol, ozone, or oxygen gas. In certain embodiments, the aluminum alkyl is trimethylaluminum.

Another aspect involves an apparatus for processing a substrate, the apparatus including: one or more process chambers, each process chamber comprising a chuck; one or more gas inlets into the process chambers and associated flow-control hardware; and a controller having at least one processor and a memory, wherein the at least one processor and the memory are communicatively connected with one another, the at least one processor is at least operatively connected with the flow-control hardware, and the memory stores computer-executable instructions for controlling the at least one processor to at least control the flow-control hardware by: exposing a metal oxide film to a boron halide reactant and igniting a first plasma with a first bias power to modify a surface of the metal oxide film; exposing the modified surface of the metal oxide film to a second plasma at a second bias power and for a duration sufficient to remove the modified surface without sputtering; and selectively depositing a metal oxide material on the metal oxide film to fill crevices on the metal oxide film.

These and other aspects are described further below with reference to the drawings.

### BRIEF DESCRIPTION OF THE DRAWINGS

FIG. 1 is a schematic illustration of an example of atomic layer etching (ALE) of film on a substrate.

FIG. 2 is a schematic illustration of an example of performing ALE on a resist with a protrusion.

FIG. 3 is a schematic illustration of an example of a removal operation during ALE.

FIG. 4 is a schematic illustration of a selective deposition cycle that may be used in accordance with certain disclosed embodiments.

FIG. 5 is a process flow diagram of operations performed in accordance with disclosed embodiments.

FIG. 6 is a process flow diagram of operations performed in accordance with disclosed embodiments.

FIG. 7 is a schematic diagram of an example process chamber for performing certain disclosed embodiments.

FIG. 8 is a schematic diagram of an example process apparatus for performing certain disclosed embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Patterning of thin films in semiconductor processing is used in the manufacture and fabrication of semiconductor devices. Conventional patterning involves photolithography, such as 193 nm lithography. In photolithography, patterns are printed by emitting photons from a photon source onto a mask and printing the pattern onto a photosensitive photoresist (PR), thus causing a chemical reaction in the PR that removes certain portions of the PR to form the pattern. As devices shrink, the need for printing smaller features increases. Although multiple patterning techniques have been developed for use with conventional photolithography, multiple patterning uses multiple layers of deposition and etching processes. Scaling of features on advanced semiconductor integrated circuits (ICs) and other devices has driven lithography to improve resolution by moving to ever smaller imaging source wavelengths.

Extreme ultraviolet (EUV) lithography has been developed to print smaller patterns on a PR using EUV light sources at approximately 13.5 nm wavelength in leading-edge lithography tools, which are also referred to as scanners. Although next generation EUV was first expected in 2006 to support 45 nm technology node manufacturing, such developments have been long delayed due to several productivity issues. One challenge in EUV productivity has been generating sufficient power to perform patterning due to the inherent difficulty creating and focusing 13.5 nm photons. The system throughput, and hence overall cost and productivity, is determined by the ratio of photons delivered at the wafer to the ratio of photons required to image the PR. Although there have been methods developed over the last decade directed to modifying the source, methods have not yet achieved a source power of 250 W for a 45 nm technology node to permit efficient use of EUV techniques. The source power used to perform EUV increases as devices shrink due to shot noise and resist blur such that to perform EUV in the 5 nm technology node, a source power of 500 W-1000 W is used to be cost competitive with existing patterning technologies.

Insufficient source power results in a loss of pattern fidelity, both in the edge roughness of patterned images as well as in the defined critical dimension, particularly for via imaging. This is due to, in addition to other reasons, the low number of photons available to image each via, stochastic variations in the number of photons in each feature and the efficiency of each photon in creating a photoacid result in random variations in hole size (also referred to as local critical dimension uniformity, or “LCDU” as referred to herein) and edge roughness (also referred to as line edge roughness, or “LER” as referred to herein).

Current techniques for patterning PRs for small critical dimension devices includes a reactive ion etching (“RIE”) process to harden, “smoothen” (e.g., reduce protrusion height and/or fill crevices), and remove residue from a PR. However, current RIE processes are unable to address LER or LCDU. For example, PRs that have been processed by ME may still have various undesirable accumulated materials such as small stringers between features and resist scum located on or near the bottom of features.

Such undesirable roughness of the pattern may transfer into the substrate beneath the patterned PR. To address this roughness, an explicit smoothening step or additional processing steps may be applied to the PR and have demonstrated a desirable reduction of surface roughness of the pattern. With advanced semiconductor fabrication techniques migrating towards EUV lithography, increased stochastic processes, radiation chemistry, as well as the usage of novel PR systems, such considerations must also be addressed while simultaneously meeting tighter surface roughness targets at smaller feature dimensions. Such demands may benefit from the development of new methods to smoothen patterned PR roughness.

Specific roughness related issues are often observed in organic chemically-activated PR systems, which may suffer from resist “blur,” due to the diffusion of photoacids and activating electrons in the PR pattern. In EUV systems, this issue may be severe, as incident photons provided by EUV are too high in energy to convert the photoacids they strike, and thus must first generate electrons at lower energy levels through photon absorption in the PR, e.g., via radiation chemistry. Common challenges include generating a sufficiently bright source of EUV radiation that will, in turn, necessitate amplification of each generated electron in a cascade reaction, potentially leading to the additional loss of PR pattern fidelity.

Moreover, as observed in organic PR systems, cycling deposition of carbon-based films with a carbon-based atomic layer etch (ALE) self-limiting trim process have demonstrated reduction of surface roughness and feature-to-feature variation due to, for example, photon stochastics and resist blur.

A potential improvement of resist blur associated with EUV exposures may be achieved through the use of a metal ligand. Under EUV exposure, such metal ligands can directly convert to a metal oxide, bypassing the resist amplification and associated resist blur. This metal oxide can subsequently act as a hardmark used to pattern an underlayer, which may contain carbon materials. By the direct absorption of high-energy EUV photons, such systems can dramatically improve PR blur otherwise inherent in organic chemically amplified systems.

However, due to the low power levels available in EUV, even metal-oxide based mask materials may benefit from techniques to reduce surface roughness due to photon stochastics and any residual blur in the metal ligand-to-oxide transition. Application of metal oxide via deposition, e.g., chemical vapor deposition (CVD) or atomic layer deposition (ALD), followed by atomic layer etch (ALE), thermal or plasma-based, of the metal oxide may together smoothen the metal oxide patterned PR for LER reduction, LCDU improvement and CD control. Treatment processes would generally be cyclic, e.g., deposition, followed by etch, with optional repeating of the same. Accordingly, loading may be leveraged, either in the deposition or etch step, to reduce feature-to-feature variations, while simultaneously maintaining desirable CD targets with a corresponding loading-independent ALD or ALE.

Provided herein are methods and apparatuses for processing semiconductor substrates to smoothen a metal oxide film, such as a patterned metal oxide film provided on a substrate having carbon-containing material. The metal oxide film may be used as a mask, such as a next-generation type of EUV photoresist (PR), to generate uniformly etched and smooth edges in imaged features after photolithography. Such techniques improve LCDU including LER of the features etched in the substrate. Disclosed embodiments reduce the need for using a high source power to perform EUV applications, thereby improving EUV scanner productivity. Also, disclosed embodiments are suitable in conjunction with etching substrates to form structures such as contacts to a source/drain region, 3-D contact holes, and more. Further, disclosed embodiments involve etch and deposition processes conducted selectively on the metal oxide film relative to the substrate positioned there-beneath. The etching and deposition processes “smoothen” the metal oxide film, e.g., reduce the undesirable non-uniformity of the metal oxide film, without otherwise disturbing or damaging the carbon-containing material of the underlying substrate.

Methods involve atomic layer etching (ALE) and selective deposition to gently etch and smoothen material, such as metal oxide material. Examples of metal oxide materials that may be etched using disclosed embodiments include metal oxide PRs, such as those generated from tin (Sn), hafnium (Hf), zirconium (Zr) and/or the like.

ALE is a technique that removes thin layers of material using sequential self-limiting reactions. Generally, ALE may be performed using any suitable technique. Examples of atomic layer etch techniques are described in U.S. Pat. No. 8,883,028, issued on Nov. 11, 2014; U.S. Pat. No. 8,808,561, issued on Aug. 19, 2014; and U.S. Pat. No. 9,576,811, issued on Feb. 21, 2017, which are herein incorporated by reference for purposes of describing example atomic layer etch and etching techniques. In various embodiments, ALE may be performed with plasma, or may be performed thermally.

ALE may be performed in cycles. The concept of an “ALE cycle” is relevant to the discussion of various embodiments herein. Generally an ALE cycle is the minimum set of operations used to perform an etch process one time, such as etching a monolayer. The result of one cycle is that at least some of a film layer on a substrate surface is etched. Typically, an ALE cycle includes a modification operation to form a reactive layer, followed by a removal operation to remove or etch only this modified layer. The cycle may include certain ancillary operations such as sweeping one of the reactants or byproducts. Generally, a cycle contains one instance of a unique sequence of operations. As an example, an ALE cycle may include the following operations: (i) delivery of a reactant gas (adsorption), (ii) purging of the reactant gas from the chamber, (iii) delivery of a removal gas and an optional plasma (desorption), and (iv) purging of the chamber.

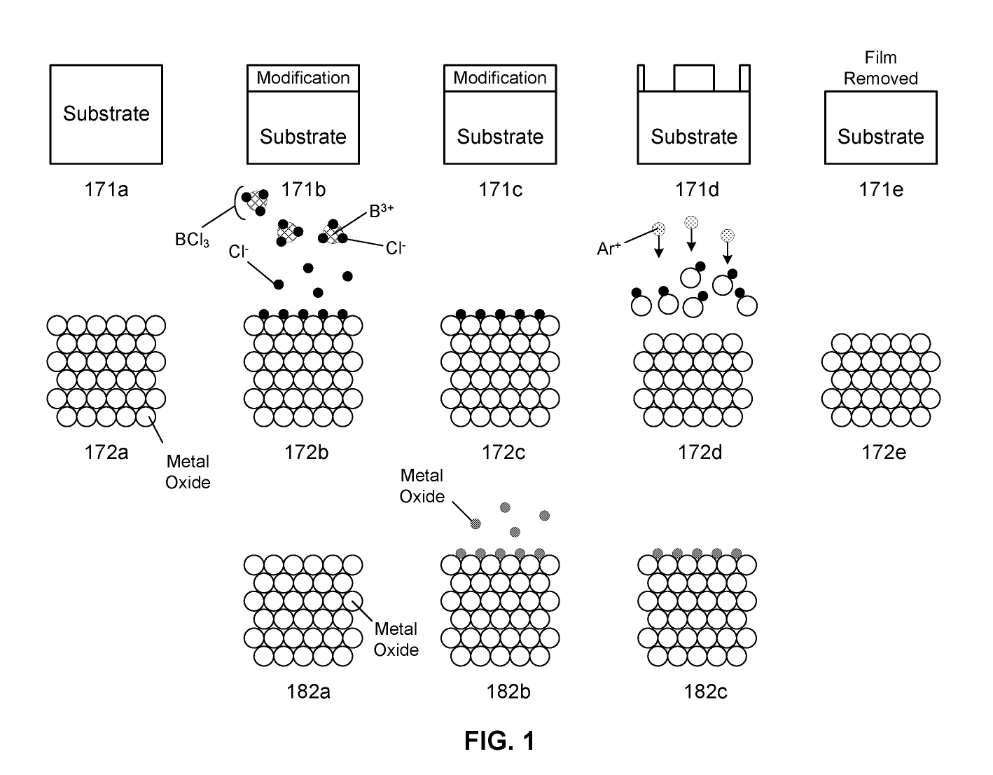

FIG. 1 shows two example schematic illustrations of an ALE cycle and a schematic illustration of selective deposition. Diagrams 171a-171e show an example ALE cycle. In 171a, a metal oxide film or substrate is provided. The metal oxide substrate may be provided on a carbon-containing layer (not shown). In certain embodiments, the metal oxide substrate may be patterned on an underlying carbon layer containing carbon material, all provided on a semiconductor substrate, such as a silicon wafer. The term “metal oxide substrate” is used herein to denote a metal oxide film or substrate as described, while “wafer” will be used to generally refer to a silicon wafer upon which the metal oxide substrate (and a carbon-containing layer there-beneath) may be provided.

In various embodiments, the metal oxide film or substrate may be provided on a silicon wafer, e.g., a 200-mm wafer, a 300-mm wafer, or a 450-mm wafer, including wafers having one or more layers of material, such as dielectric, conducting, or semi-conducting material deposited thereon. In some embodiments, the wafer may include a blanket layer of silicon, such as amorphous silicon, or a blanket layer of germanium. The wafer may include a patterned mask layer previously deposited and patterned on the wafer. For example, a mask layer may be deposited and patterned on a substrate including a blanket metal oxide layer.

In some embodiments, the layers on the wafer may be patterned. Wafers may have “features” such as via or contact holes, which may be characterized by one or more of narrow and/or re-entrant openings, constrictions within the feature, and high aspect ratios. The feature may be formed in one or more of the above described layers. One example of a feature is a hole or via in a semiconductor wafer or a layer provided on the wafer. Another example is a trench defined by a line or space in a wafer or layer provided thereon. In various embodiments, the feature may have an under-layer, such as a barrier layer or adhesion layer. Non-limiting examples of under-layers include dielectric layers and conducting layers, e.g., silicon oxides, silicon nitrides, metal oxides, metal nitrides, metal layers, silicon carbides, metal carbides, and other carbon-containing layers, such as amorphous carbon.

In 171b, the surface of the metal oxide film, substrate or layer is modified. In 171c, the modified layer remains after a purge operation to remove excess non-adsorbed precursor. In 171d, the modified layer is being etched. In 171e, the modified layer is removed.

Similarly, diagrams 172a-172e show an example of an ALE cycle for etching a metal oxide film. In some embodiments, diagrams 172a-172e refer to ALE cycles performed on a zirconium oxide (ZrO₂) layer provided on an underlying carbon-containing layer (not shown). In 172a, a substrate including metal oxide material is provided.

In 172b, a modifier, such as boron trichloride (BCl₃) gas, is introduced to the metal oxide layer to modify the exposed surface of the metal oxide layer. The selection of the type of modifier employed may depend at least in part on the type of metal oxide material. In some embodiments, a boron trichloride (BCl₃) gas may be desirable modifier, particularly to achieve selectivity to an underlying carbon material. Other suitable metal oxide film modifiers that may be used in the described context include chlorine gas (Cl₂) and hydrogen chloride gas (HCl).

The schematic in 172b shows that some modifier, e.g., BCl₃, is adsorbed onto the surface of the metal oxide layer as an example. The modifier dissociates in a modification operation, e.g., BCl₃ dissociates to form multiple individual separate Cl— ions, which form a thin, reactive surface layer on the metal oxide layer. The reactive surface layer may be a metal chloride, e.g., having an approximate chemical formula of MClₓ, with a thickness that is more easily removed than the un-modified material positioned beneath the surface layer in the subsequent removal operation. In such circumstances using BCl₃ as the modifier, dissociated boron (B) may react with oxygen provided by the metal oxide layer to form boron oxide (BO), which may be evacuated from the reaction chamber as needed. A modifier-containing plasma may be also used during the modification, or adsorption, operation. Modifier-containing plasma may be generated by flowing a modification chemistry such as BCl₃ gas and igniting a plasma. Other modifier chemistries suitable for forming plasmas include reactants and/or reagents such as chlorine gas (Cl₂), hydrogen gas (H₂), and hydrogen bromide (HBr). Additional reactants may include compounds and species, such as chlorine (Cl), bromine (Br) and/or iodine (I), which can be reactively bound to the metal oxide surface and subsequently volatized using a sub-sputter threshold ion bombardment. These modifiers may be used by themselves or in combination, including with diluent inert gases such as helium (He), argon (Ar), neon (Ne), krypton (Kr), xenon (Xe), and combinations thereof. Modifiers may be selected and applied based on their ability to volatilize metal provided by the metal oxide layer, for example, BCl₃. Alternatively, in certain embodiments, diborane gas (B₂H₆) may be used in place of BCl₃ to similarly volatilize metal from the metal layer. As shown by 172a-172e in FIG. 1, this operation modifies a few angstroms of the metal oxide material surface to form a modified layer having weaker bond energies than bulk metal oxide material beneath the modified surface.

In various embodiments, the modifier is provided to the metal oxide substrate as a plasma with no or a low bias. For example, in various embodiments, the modifier is introduced to a plasma processing chamber and a plasma source power is turned on to ignite a plasma to facilitate adsorption of the modifier onto the surface of the carbon-containing material. The bias may be applied at a low power or voltage, such as a self-bias between about 5V and about 15V or up to about 50V. It will be understood that the terms “bias power” and “bias voltage” are used interchangeably herein to describe the voltage for which a pedestal is set when a bias is applied to the pedestal. Bias power or bias voltage as described herein is measured in volts, which are indicated by the unit “V” or “Vb”, where b refers to bias.

In certain embodiments, the schematic shown in 172b involves a two-step process. For example, to conduct ALE of a zirconium oxide (ZrO₂) layer or substrate provided upon a carbon-containing layer (not shown): (1) boron tricholoride (BCl₃) gas is provided to a reaction chamber where the ALE processes are conducted at a pressure of 60 mTorr, and at a plasma power setting of 300-900 W. The plasma may be provided from an inductively coupled plasma (ICP) source. A 0 V bias voltage may be applied to a pedestal holding or supporting the substrate with the metal oxide layer thereon for a duration of 5 seconds at a temperature range of 0-60° C.; next (2) chlorine (Cl₂) gas is provided to the same reaction chamber where the ALE processes are conducted at a pressure of 10 mT, and at a plasma power setting of 100-300 W. The bias voltage applied may range from 0-100V and may be applied for a duration of 5 seconds at a temperature range of 0-60° C.

At a temperature of 0° C., a plasma power setting of 300 W may be used for both steps, and with a bias voltage of 100V applied at step (2), an approximate etch rate of 1.1 Å/cycle may be observed. Further variations of the above-described two-step process may again involve substitution of argon (Ar) gas in place of Cl₂ to achieve an approximate etch rate of 5 Å/cycle.

In other embodiments, ALE may be employed to etch aluminum oxide (Al₂O₃). However, unlike ALE of ZrO₂, ALE of Al₂O₃ does not show a significant etch rate with the application of chlorine (Cl₂) gas in step (2). Accordingly, successful ALE of Al₂O₃ typically requires application of an argon-derived plasma in step (2).

Returning to that shown by FIG. 1, in 172c, the modifier chemistry is purged from the chamber. In 172d, a removal gas argon is introduced with a directional plasma as indicated by the Ar⁺ plasma species and arrows, and ion bombardment is performed to remove the modified metal oxide surface of the metal oxide substrate. During this operation, a bias is applied to the metal oxide substrate to attract ions toward it. In the desorption operation, an inert gas plasma (such as He, Ar, Xe, or N₂) may be used to remove the modified layer. Although argon is depicted in 172d, it will be understood that any suitable inert gas may be used to generate a plasma for this operation. The bias power applied during removal may be between about 30V and about 100V in various embodiments. The bias power may be selected such that the energy provided to the metal oxide substrate is less than the energy required to sputter the metal oxide substrate but greater than the energy used to remove the modified layer from the metal oxide substrate. The plasma power may be set at a power between about 30 W and about 500 W.

In 172e, the chamber is purged and the byproducts are removed. In various embodiments, between about 1 Å and about 130 Å of material may be removed in one cycle. The post-etch surface of the metal oxide material is typically smooth after an ALE process. For example, in some embodiments, the root mean square roughness of the surface after an ALE process may be less than about 0.5 nm (Rᵣₘₛ<0.5 nm).

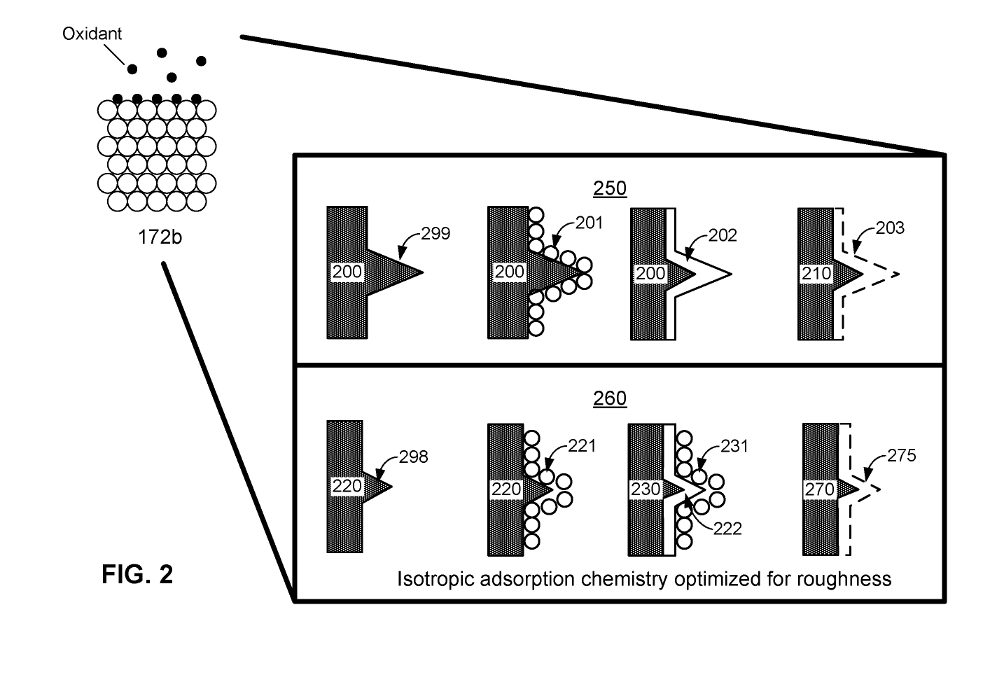

FIG. 2 shows how this operation can reduce the presence of protrusions on a metal oxide photoresist PR. The size of protrusions on the metal oxide PR may be range from about 1 Å to about 30 Å in diameter and/or in height. An example metal oxide containing substrate 200 having resist material and a protrusion 299 is provided as shown in FIG. 2. A weak modifier 201 is provided and adsorbs onto the metal oxide substrate 200, which modifies the surface of the metal oxide substrate 200 to form modified surface 202. The modified surface 202 is then removed; the dotted line 203 shows where the previous metal oxide material was on the metal oxide substrate 200 to now yield metal oxide substrate 210. This process 250 may constitute one ALE oxidation cycle. Process 260, shown beneath process 250, shows a metal oxide substrate 220 having a protrusion 298, which is exposed to a weak modifier 221. Protrusion 298 may be smaller in volume and/or shorter in height than protrusion 299. The weak modifier 221 adsorbs onto the metal oxide substrate 220 which modifies the surface of the metal oxide substrate 220 to form modified surface 222. Weak modifier 231 adsorbs onto metal oxide substrate 230 to form a modified layer (not shown) and the modified layer is further removed to yield metal oxide substrate 270, which includes a dotted line 275 showing where the previous metal oxide containing material was on the metal oxide substrate 230.

Without adherence to or being limited by a particular theory, the scale of the metal oxide containing protrusions 299 and 298 shown in FIG. 2 is believed to be on the atomic level. Thus, the protrusions 299 and 298 have a substantial surface area to volume ratio, largely on account of their small (e.g., atomic) size. As introduced and discussed above, one or more weak modifiers are sequentially adsorbed onto the exposed surfaces of the metal oxide containing protrusions to modify such surfaces for subsequent removal. In detail, adsorption of the weak modifier onto the metal oxide protrusion modifies a layer of metal oxide material thereon, e.g. each layer being 3 to 4 atoms and/or atomic layers in thickness, suitable for subsequent removal. Accordingly, the height and/or overall size of the protrusions may be systematically reduced upon completion of sequential ALE operations, e.g. with each ALE operation functioning to remove one modified layer from the protrusion until the protrusion itself is substantially reduced and/or removed, ultimately “smoothening” the surface originally with the protrusion relative to its surrounding flat areas. Further, in certain embodiments, ALE chemistries may be optimized per surface roughness, e.g. dependent on the height of the protrusions sought to be removed.

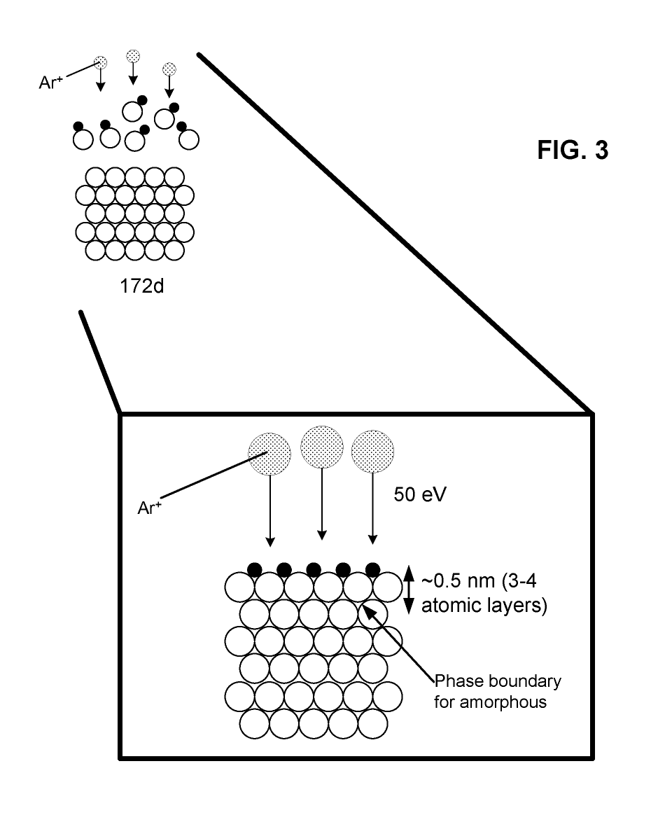

FIG. 3 shows how removal operations, e.g. as discussed above and shown by 172d in FIG. 1, can improve smoothening of material being etched. The inert plasma species used in 172d is applied with a low bias such that the plasma species has enough energy to remove the modified surface of the weak modifier adsorbed onto metal oxide atoms on the surface of the metal oxide substrate. However, the inert plasma species, as applied, does not have enough energy to sputter the underlying non-modified metal oxide atoms beneath the top exposed surface of the metal oxide substrate. In various embodiments, bias applied may be between about 30V and about 100V, or less than about 50V. In some embodiments, each modified layer may be about 0.5 nm thick, which may include about 3 to 4 atomic layers. In some embodiments there may be a phase boundary between the modified layer and underlying amorphous material as shown in FIG. 3. The inert plasma species, such as Ar⁺ shown in FIG. 3, may be a sub-threshold, non-reactive ion species, where sub-threshold means the energy of the inert plasma species is insufficient to sputter the material underlying the modified layer but high enough to remove the modified layer. A threshold bias power or threshold bias voltage refers to the maximum voltage of the bias applied to a pedestal before material on the surface of a substrate, e.g., a metal oxide containing substrate, or a substrate with a metal oxide layer provided thereon, on the pedestal is sputtered. The threshold bias power therefore depends in part on the material to be etched, the gas used to generate plasma, plasma power for igniting the plasma, and plasma frequency. After each cycle, the surface may be “reset” such that surface includes material to be removed without much or any modified material on the surface.

Further description about smoothening substrates using ALE techniques is described in U.S. Provisional Patent Application No. 62/214,813, entitled “ALE SMOOTHNESS: IN AND OUTSIDE SEMICONDUCTOR INDUSTRY” filed on Sep. 4, 2015, and U.S. Patent Application Publication No. 2017/0069462, filed Aug. 31, 2016 and entitled “ALE SMOOTHNESS: IN AND OUTSIDE SEMICONDUCTOR INDUSTRY”, which are herein incorporated by reference in their entireties. Without being bound by a particular theory, it is believed that substrates may be smoothened by disclosed embodiments due to the layer-by-layer mechanism by which ALE etches material, thereby etching and smoothening protrusions on a surface of the substrate during each cycle. For example, a protrusion on the surface of material to be smoothened may be modified and etched on the surfaces of the protrusions such that as the protrusion is etched, the size of the protrusion shrinks with each etching cycle, thereby smoothening the surface of the material.

Although ALE processes can smoothen, as described above, sidewall or line edge roughness, ALE processes cannot change critical dimension (CD) variation, e.g. line width or hole/pillar diameters. To do this, a selective metal oxide deposition process is used to selectively deposit on the metal oxide layer and preferentially fill features therein with carbon-containing materials at different deposition rates into features of different sizes. In various embodiments, the diameters of holes or pillars are uniform over the substrate and LCDU is improved. For example, metal oxide may be used in some embodiments as a suitable deposition material. Further, in certain embodiments, deposition of metal oxides to fill features may involve an intermediate water (H₂O) conversion step.

Returning to FIG. 1, 182a-182c show an example schematic illustration of selective deposition processes that may be performed in accordance with certain disclosed embodiments. For selective metal oxide deposition on a metal oxide layer relative to a carbon-containing substrate (not shown) positioned beneath the metal oxide layer, 182a shows a substrate with metal oxide atoms. In 182b, the metal oxide is exposed to a metal oxide-containing chemistry such as zirconium oxide (ZrO₂) such that ZrO₂ material selectively deposits onto the surface of the zirconium oxide substrate selective to carbon-containing materials positioned beneath the metal oxide film. In some embodiments, the metal oxide-containing chemistry may be combined with one or more diluents to generate a plasma. Example diluents include nitrogen, helium, argon, hydrogen, and combinations thereof. In 182c, the chamber is purged to remove excess metal oxide, leaving only specified quantities of metal oxide on the surface of the metal oxide substrate or layer.

In certain embodiments, ZrO₂ can be deposited by ALD processes, such as those shown by 182a-182c in FIG. 1, using thermally-driven half reactions of a zirconium (Zr)-containing precursor (e.g., zirconium amide, zirconium halide, or zirconium alkoxide) and an oxygen-containing (O) precursor (e.g., water, alcohol, ozone, oxygen) to generate the ZrO₂ used for deposition by ALD. Deposition dosage times and pressures may depend upon the type of precursor used. For example, for zirconium amide and water, a 1 second dosage time at a partial pressure of 10 mTorr is sufficient to achieve a saturated thickness of 1 Å/ALD cycle. In contrast, halide and/or alkoxide precursors generally require higher dosage times or exposure. Also, the temperature at which deposition is conducted via ALD processes is typically dependent on the thermal stability of the metal source used, e.g. zirconium used as a metal source to generate zirconium oxide. For example, zirconium amide precursors are typically acceptable within a range extending from room temperature, e.g. about 20° C.-25° C., toward 250° C. Alternatively, in certain embodiments, ALD of aluminum oxide (Al₂O₃) can be performed in a similar manner as ZrO₂ ALD with similar constraints, but in addition to amide, halide, and alkoxide precursor choices, aluminum alkyls (i.e., trimethylaluminum) can also be used.

Moreover, in certain embodiments, metal oxide can be deposited on a metal oxide layer via ALD processes selectively relative to a carbon-containing substrate beneath the metal oxide layer. With respect to such a selective deposition of metal oxide, the oxygen-containing precursor used should not oxidize the carbon under the conditions described above. Oxygen-containing precursors suitable for use in metal oxide ALD include water (H₂O) and alcohol (R—OH).

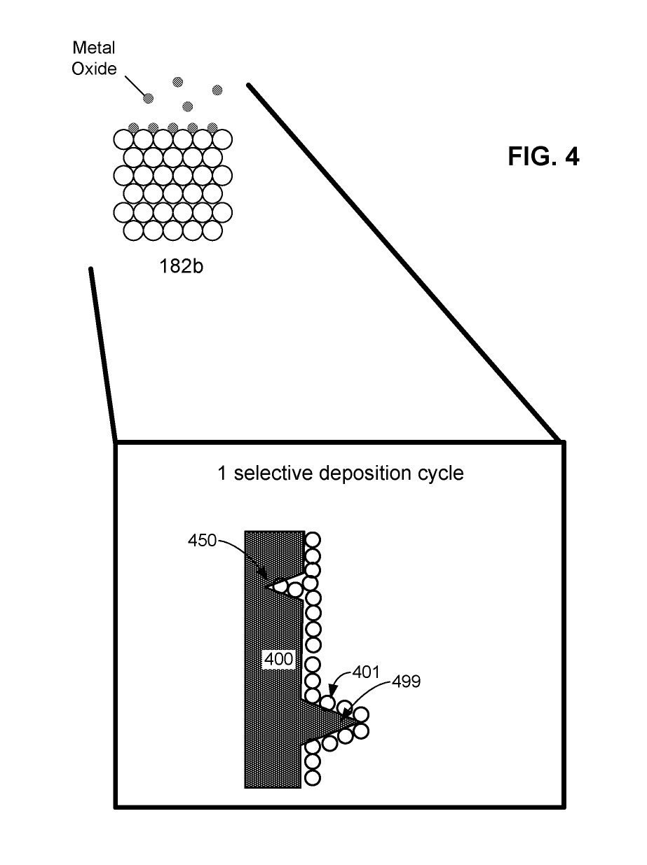

FIG. 4 shows how selective metal oxide deposition can reduce the presence of recessions in the surface of the metal oxide containing layer, film or substrate 400 to smoothen the same. As introduced earlier, the smoothened metal oxide layer may be used as a PR mask to etch a carbon-based substrate positioned beneath the metal oxide film resulting in improved local critical dimensions (LCD) of the features etched in the carbon-based substrate. During 182b, the metal oxide containing chemistry is delivered to the metal oxide containing substrate 400 and adsorbs to the surface of the metal oxide containing material on the substrate 400. Metal oxide material may be deposited via the ALD processes described above into crevices, such as crevice 450 shown in FIG. 4, formed in the metal oxide containing layer, or substrate, 400, to fill the crevice 450 with metal oxide material to smoothen the crevice relative to the surrounding flat areas of the metal oxide containing layer 400. Such deposition of metal oxide material via ALD may be a self-limiting process.

Further, and also as shown in FIG. 4, selective deposition via ALD processes described above may include deposition on protrusions (499), such as on a photoresist. Similar to that described earlier for reducing and/or removing protrusions via ALE processes, ALD is particularly useful to fill crevices on the surface of the metal oxide layer. Such crevices, similar to the protrusions, may be at the atomic level scale, and thus also have high surface-area-to-volume (e.g., empty volume) ratios. Without being bound by a particular theory, it is believed that since the scale of the crevices on the surface of the metal oxide may be on the atomic level, depositing a metal oxide into these crevices such that deposited metal oxide is adsorbed uniformly onto the surface of the substrate will result in more material being deposited in a crevice than on the adjacent relatively flat surface of the substrate, thereby reducing the presence of crevices with each deposition cycle. Thus, deposition of metal oxide material on exposed surfaces within a crevice in the metal oxide layer may be conducted to fill the same, effectively smoothening the crevice relative to the surrounding flat areas of the metal oxide layer.

In some embodiments, the substrate may also be exposed to an inert plasma after exposing the substrate to the metal oxide containing chemistry. The inert plasma may be generated by flowing any one or more of hydrogen, helium, nitrogen, argon, and neon and igniting a plasma. The plasma may be ignited using a plasma power between about 30 W and about 500 W. Without being bound by a particular theory, it is believed that exposing the substrate to the inert plasma allows the adjacent surface to the metal oxide containing material on the substrate such as a PR to be slightly etched and/or refreshed to prevent deposition, hence resulting in selective deposition. Exposures to the metal oxide-containing chemistry and inert plasma may be performed in one or more cycles.

Further, in some embodiments, metal oxide deposition may be conducted by a variation of the ALD processes described above involving use of silicon (Si) or tin (Sn) reagents provided with an oxide-based plasma. A slight bias may be applied to the pedestal supporting the metal oxide containing substrate to direct deposition flow thereto.

Using a combination of ALE techniques as described herein and selective ALD, metal oxide materials on a substrate may be processed to result in smoothened, uniform features, particularly useful for EUV applications.

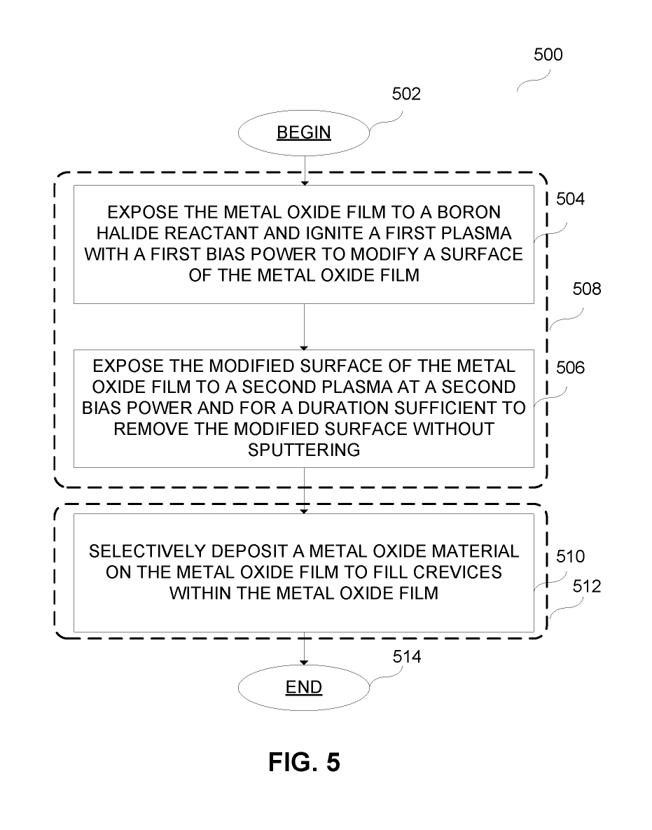

FIG. 5 shows a simplified process flow diagram of process flow 500 that shows ALE process 508 followed by ALD process 512 to reduce protrusions on and fill crevices within the metal oxide containing layer, or film, respectively. Process flow 500 initiates at operation 502 and progresses to operation 504, which involves exposure of the metal oxide film to a boron halide reactant. A first plasma is ignited with a first bias power to modify an exposed surface of the metal oxide film. Next, the modified surface of the metal oxide film, at operation 506, is exposed to a second plasma at a second bias power for a duration sufficient to remove the modified surface without sputtering. Processes conducted in operations 504 and 506 may collectively be referred to as ALE processes 508 and carried out to reduce and/or remove surface protrusions as described earlier in FIGS. 2 and 3. Next, metal oxide material is selectively deposited to fill crevices within the metal oxide film at operation 510. Deposition is conducted via ALD and is selective relative to the carbon-containing substrate upon which the metal oxide containing film resides. Process flow 500 then ends at operation 514. One skilled in the art will appreciate that process flow 500 may be conducted one or more times as needed to achieve desired smoothness levels and/or may be further tuned to achieve specific smoothness targets.

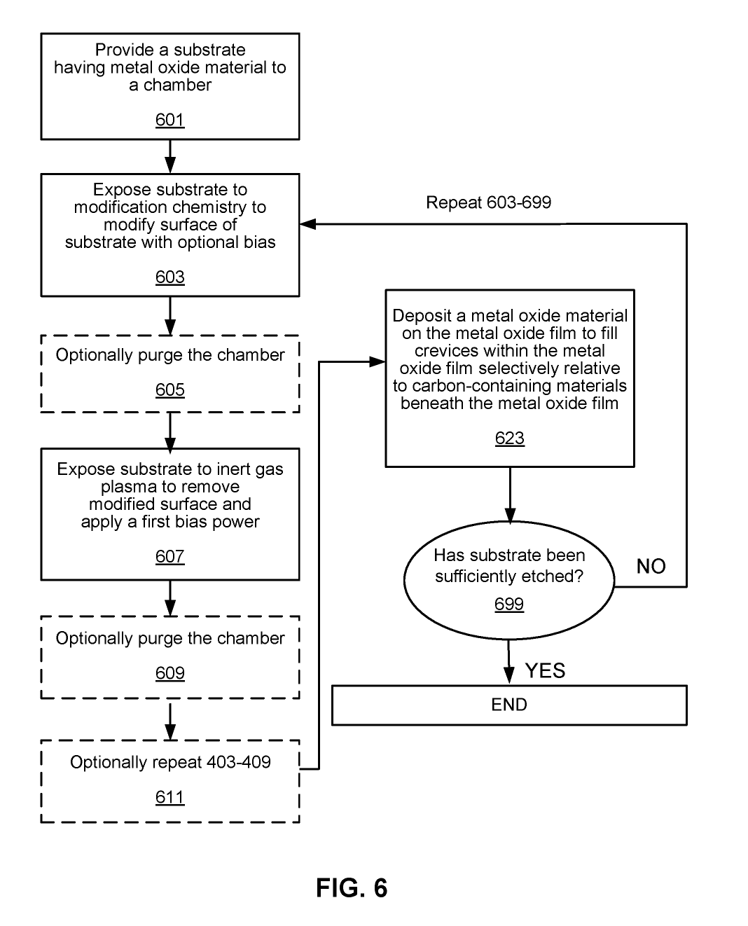

FIG. 6 is a detailed process flow diagram of an embodiment where ALE and selective carbon deposition are performed. Operations of FIG. 6 may be performed in a chamber having a chamber pressure between about 5 mTorr and about 100 mTorr. Operations of FIG. 5 may be performed at a substrate temperature between about 20° C. and about 250° C. Substrate temperature will be understood to mean the temperature at which the pedestal or wafer holder which holds the substrate is set at. The operations shown in FIG. 6 summarize operations performed as described above with respect to FIG. 1. For example, in operation 601, a substrate including a metal oxide containing material is provided to a chamber. As described above, the metal oxide containing material may include zirconium oxide (ZrO₂). Operation 601 may correspond with the schematic illustration depicted in 171a and 172a of FIG. 1. In operation 603, the substrate is exposed to a modification chemistry such as a strong or a weak modifier to modify a surface of the substrate. In various disclosed embodiments, the metal oxide containing material on the surface is modified. This operation may correspond with the schematic illustration depicted in 171b and 172b of FIG. 1 and FIG. 2. In operation 605, the chamber is optionally purged to remove excess modification chemistry (such as a weak modifier, i.e. CO₂) from the chamber. This operation may correspond to 172d of FIGS. 1 and 3. The chamber may be purged by evacuating the chamber or stopping the flow of the modification chemistry and flowing a non-reactive inert gas, such as helium or argon, to remove the excess gas phase modification chemistry. In operation 607, the substrate is exposed to an inert gas plasma to remove the modified surface. During operation 607 a bias is applied to generate enough energy for the inert gas plasma to remove the modified surface without sputtering the substrate. In operation 609, the chamber is optionally purged to remove modified material in gas phase from the chamber. In operation 611, the operations 603-609 may be optionally repeated in cycles. In operation 623, the substrate is exposed to a metal oxide containing chemistry to adsorb a layer of metal oxide containing material onto the substrate. This may be used in some embodiments to fill crevices on the metal oxide containing surface of the substrate. This operation may correspond to 182a of FIGS. 1 and 4. In some embodiments, the substrate may be purged one or more times between performing any of the described operations. In various embodiments, operations 603-699 may be optionally repeated in one or more cycles that may each be performed with or without purge operations as shown. In operation 625, the chamber may be optionally purged. It will be understood that purging operations as described herein may be performed by pumping gases from the chamber, by flowing one or more inert gases, or combinations thereof using any suitable purging technique. In operation 699, it is determined whether the substrate has been sufficiently etched to form the desired surface on the substrate. If not, operations 603-699 may be optionally repeated for n cycles, where n is an integer equal to or greater than 1. In some embodiments, operation 423 is repeated only in some but not all repeated cycles, while in some embodiments, operations 623 is repeated in every cycle.

By combining ALE processes and selective ALD processes, both LCDU and LER of metal oxide containing PR features are improved. In certain embodiments, this improvement may then be transferred to an underlying hard mask (such as a SiO₂/SiN layer), and consequently to structures of interest resulting in improved variability and performance of the devices.

The ALE operations disclosed above are gentle and precise which removes a digital amount of material per cycle so can be easily controlled to not overetch the soft metal oxide PR material. Similarly, the metal oxide selective deposition may use a low source power (e.g., transformer couple plasma or TCP) and no bias, and deposition can be performed without damaging the resist.

In some embodiments, selective metal oxide deposition may be optional. For example, these certain embodiments may be used in applications where critical dimension increase can be tolerated.

In certain embodiments, a combination of disclosed ALE operations and selective metal oxide deposition may be used on a metal oxide containing material to improve LCDU and recover the critical dimension if the original critical dimension is to be maintained throughout a patterning process using a photoresist.

Apparatus

Disclosed embodiments may be performed in any suitable etching chamber or apparatus, such as the Kiyo® FX, available from Lam Research Corporation of Fremont, Calif. Another example of a plasma etch chamber that may be employed is a Flex™ reactive ion etch tool available from Lam Research Corp. of Fremont, Calif. Further description of plasma etch chambers may be found in U.S. Pat. Nos. 6,841,943 and 8,552,334, which are herein incorporated by reference in their entireties.

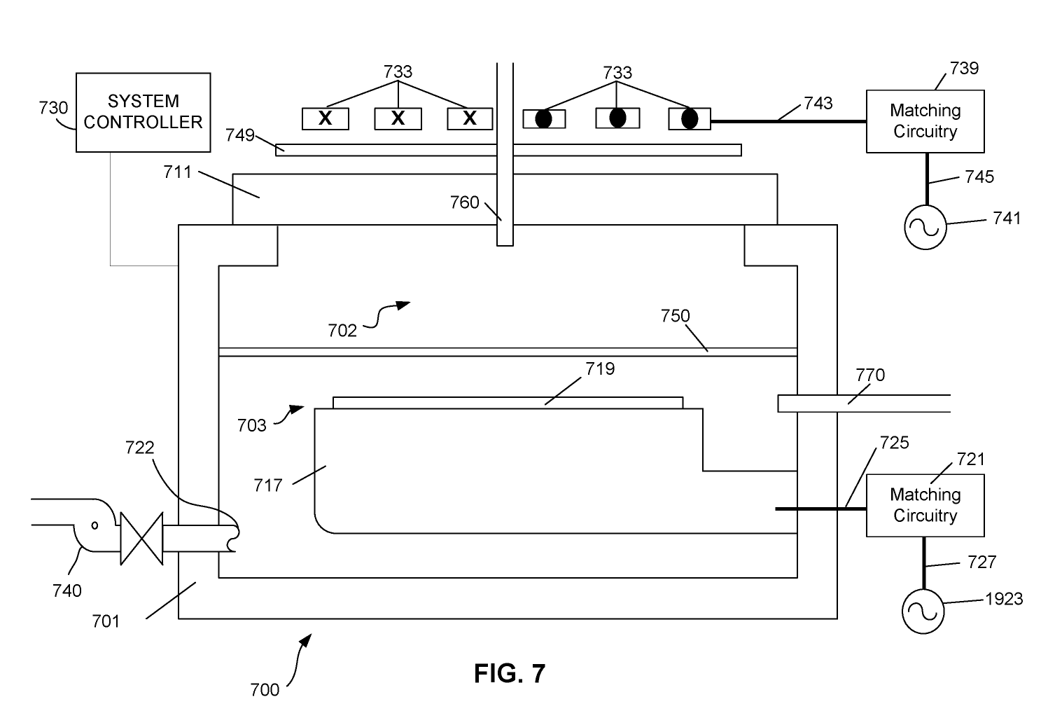

In some embodiments, an inductively coupled plasma (ICP) reactor may be used. One example is provided in FIG. 7. Such ICP reactors have also been described in U.S. Pat. No. 9,362,133 issued Jun. 7, 2016, filed Dec. 10, 2013, and titled “METHOD FOR FORMING A MASK BY ETCHING CONFORMAL FILM ON PATTERNED ASHABLE HARDMASK,” hereby incorporated by reference for the purpose of describing a suitable ICP reactor for implementation of the techniques described herein. Although ICP reactors are described herein, in some embodiments, it should be understood that capacitively coupled plasma reactors may also be used. An example etching chamber or apparatus may include a chamber having chamber walls, a chuck for holding a substrate or wafer to be processed which may include electrostatic electrodes for chucking and dechucking a wafer and may be electrically charged using an RF power supply, an RF power supply configured to supply power to a coil to generate a plasma, and gas flow inlets for inletting gases as described herein. For example, modification chemistry gases and/or selective deposition chemistry may be flowed to the etching chamber for performing ALE and/or selective deposition respectively. In some embodiments, an apparatus may include more than one chamber, each of which may be used to etch, deposit, or process substrates. The chamber or apparatus may include a system controller for controlling some or all of the operations of the chamber or apparatus such as modulating the chamber pressure, inert gas flow, plasma power, plasma frequency, reactive gas flow (e.g., weak modifier gas, carbon-containing gas, etc.); bias power, temperature, vacuum settings; and other process conditions. The chamber may also be used to selectively deposit carbon-containing material onto a substrate.

FIG. 7 schematically shows a cross-sectional view of an inductively coupled plasma integrated etching and deposition apparatus 700 appropriate for implementing certain embodiments herein, an example of which is a Kiyo™ reactor, produced by Lam Research Corp. of Fremont, Calif. The inductively coupled plasma apparatus 700 includes an overall process chamber 701 structurally defined by chamber walls 701 and a window 711. The chamber walls 701 may be fabricated from stainless steel or aluminum. The window 711 may be fabricated from quartz or other dielectric material. An optional internal plasma grid 750 divides the overall processing chamber 701 into an upper sub-chamber 702 and a lower sub-chamber 703. In most embodiments, plasma grid 750 may be removed, thereby utilizing a chamber space made of sub-chambers 702 and 703. A chuck 717 is positioned within the lower sub-chamber 703 near the bottom inner surface. The chuck 717 is configured to receive and hold a semiconductor wafer 719 upon which the etching and deposition processes are performed. The chuck 717 can be an electrostatic chuck for supporting the wafer 719 when present. In some embodiments, an edge ring (not shown) surrounds chuck 717, and has an upper surface that is approximately planar with a top surface of a wafer 719, when present over chuck 717. The chuck 717 also includes electrostatic electrodes for chucking and dechucking the wafer. A filter and DC clamp power supply (not shown) may be provided for this purpose. Other control systems for lifting the wafer 719 off the chuck 717 can also be provided. The chuck 717 can be electrically charged using an RF power supply 723. The RF power supply 723 is connected to matching circuitry 721 through a connection 727. The matching circuitry 721 is connected to the chuck 717 through a connection 725. In this manner, the RF power supply 723 is connected to the chuck 717.

Elements for plasma generation include a coil 733 is positioned above window 711. In some embodiments, a coil is not used in disclosed embodiments. The coil 733 is fabricated from an electrically conductive material and includes at least one complete turn. The example of a coil 733 shown in FIG. 6 includes three turns. The cross-sections of coil 733 are shown with symbols, and coils having an “X” extend rotationally into the page, while coils having a “.” extend rotationally out of the page. Elements for plasma generation also include an RF power supply 741 configured to supply RF power to the coil 733. In general, the RF power supply 741 is connected to matching circuitry 739 through a connection 745. The matching circuitry 739 is connected to the coil 733 through a connection 743. In this manner, the RF power supply 741 is connected to the coil 733. An optional Faraday shield 749 is positioned between the coil 733 and the window 711. The Faraday shield 749 is maintained in a spaced apart relationship relative to the coil 733. The Faraday shield 749 is disposed immediately above the window 711. The coil 733, the Faraday shield 749, and the window 711 are each configured to be substantially parallel to one another. The Faraday shield may prevent metal or other species from depositing on the dielectric window of the plasma chamber 701.

Process gases (e.g. oxygen, carbon dioxide, methane, etc.) may be flowed into the processing chamber 701 through one or more main gas flow inlets 760 positioned in the upper chamber 702 and/or through one or more side gas flow inlets 770. Likewise, though not explicitly shown, similar gas flow inlets may be used to supply process gases to a capacitively coupled plasma processing chamber. A vacuum pump, e.g., a one or two stage mechanical dry pump and/or turbomolecular pump 740, may be used to draw process gases out of the process chamber 701 and to maintain a pressure within the process chamber 701. For example, the pump may be used to evacuate the chamber 701 during a purge operation of ALD. A valve-controlled conduit may be used to fluidically connect the vacuum pump to the processing chamber 701 so as to selectively control application of the vacuum environment provided by the vacuum pump. This may be done employing a closed-loop-controlled flow restriction device, such as a throttle valve (not shown) or a pendulum valve (not shown), during operational plasma processing. Likewise, a vacuum pump and valve controlled fluidic connection to the capacitively coupled plasma processing chamber may also be employed.

During operation of the apparatus, one or more process gases may be supplied through the gas flow inlets 760 and/or 770. In certain embodiments, process gas may be supplied only through the main gas flow inlet 760, or only through the side gas flow inlet 770. In some cases, the gas flow inlets shown in the figure may be replaced more complex gas flow inlets, one or more showerheads, for example. The Faraday shield 749 and/or optional grid 750 may include internal channels and holes that allow delivery of process gases to the chamber 701. Either or both of Faraday shield 749 and optional grid 750 may serve as a showerhead for delivery of process gases. In some embodiments, a liquid vaporization and delivery system may be situated upstream of the chamber 701, such that once a liquid reactant or precursor is vaporized, the vaporized reactant or precursor is introduced into the chamber 701 via a gas flow inlet 760 and/or 770.

Radio frequency power is supplied from the RF power supply 741 to the coil 733 to cause an RF current to flow through the coil 733. The RF current flowing through the coil 733 generates an electromagnetic field about the coil 733. The electromagnetic field generates an inductive current within the upper sub-chamber 702. The physical and chemical interactions of various generated ions and radicals with the wafer 719 selectively etch features of and deposit layers on the wafer.

If the plasma grid is used such that there is both an upper sub-chamber 702 and a lower sub-chamber 703, the inductive current acts on the gas present in the upper sub-chamber 702 to generate an electron-ion plasma in the upper sub-chamber 702. The optional internal plasma grid 750 limits the amount of hot electrons in the lower sub-chamber 703. In some embodiments, the apparatus is designed and operated such that the plasma present in the lower sub-chamber 703 is an ion-ion plasma.

Both the upper electron-ion plasma and the lower ion-ion plasma may contain positive and negative ions, though the ion-ion plasma will have a greater ratio of negative ions to positive ions. Volatile etching and/or deposition byproducts may be removed from the lower-sub-chamber 703 through port 722. The chuck 717 disclosed herein may operate at elevated temperatures ranging between about 10° C. and about 250° C. The temperature will depend on the process operation and specific recipe.

Chamber 701 may be coupled to facilities (not shown) when installed in a clean room or a fabrication facility. Facilities include plumbing that provide processing gases, vacuum, temperature control, and environmental particle control. These facilities are coupled to chamber 701, when installed in the target fabrication facility. Additionally, chamber 701 may be coupled to a transfer chamber that allows robotics to transfer semiconductor wafers into and out of chamber 701 using typical automation.

In some embodiments, a system controller 730 (which may include one or more physical or logical controllers) controls some or all of the operations of a processing chamber. The system controller 730 may include one or more memory devices and one or more processors. In some embodiments, the apparatus includes a switching system for controlling flow rates and durations when disclosed embodiments are performed. In some embodiments, the apparatus may have a switching time of up to about 500 ms, or up to about 750 ms. Switching time may depend on the flow chemistry, recipe chosen, reactor architecture, and other factors.

The processing chamber 701 or apparatus may include a system controller. For example, in some embodiments, a controller 730 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 730, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller 730 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer. For example, the controller and the processor may be at least operatively connected with the flow-control hardware, and the memory may store computer-executable instructions for controlling the processor to control the flow-control hardware by: exposing a metal oxide film to a boron halide reactant and igniting a first plasma with a first bias power to modify a surface of the metal oxide film; exposing the modified surface of the metal oxide film to a second plasma at a second bias power and for a duration sufficient to remove the modified surface without sputtering; and selectively depositing a metal oxide material on the metal oxide film to fill crevices on the metal oxide film.

The controller 730, in some implementations, may be a part of or coupled to a computer that is integrated with, coupled to the system, otherwise networked to the system, or a combination thereof. For example, the controller 630 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller 730 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

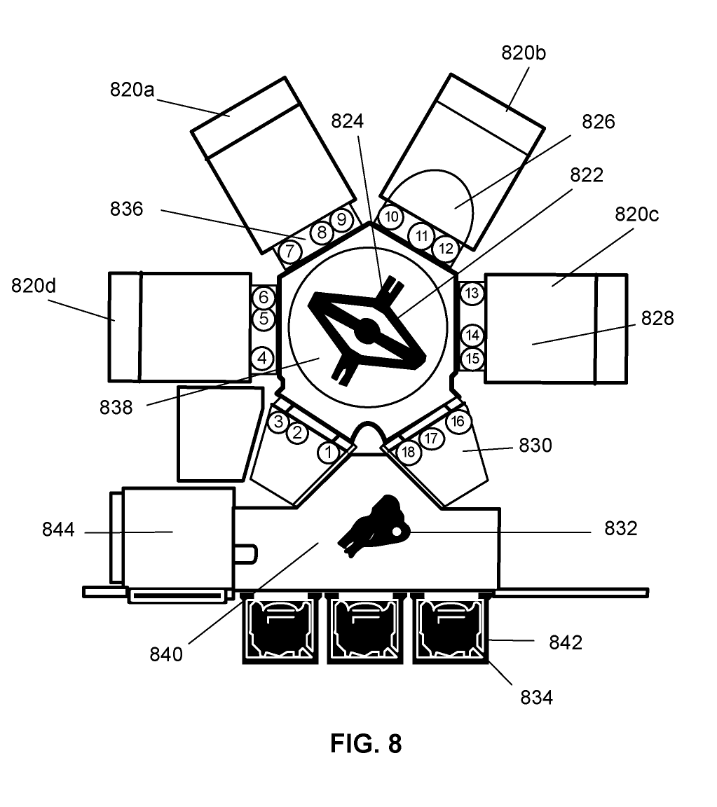

The processing chamber 701 may be integrated in a multi-station tool such as shown in FIG. 8. Each station may be used to process different operations. For example, one station may be used to perform ALE while another station is used to perform selective deposition. Disclosed embodiments may be performed without breaking vacuum and may be performed in the same apparatus. In various embodiments, ALE and selective deposition are performed without breaking vacuum. In various embodiments, ALE and selective deposition are performed in the same chamber.

FIG. 8 depicts a semiconductor process cluster architecture with various modules that interface with a vacuum transfer module 838 (VTM). The arrangement of transfer modules to “transfer” wafers among multiple storage facilities and processing modules may be referred to as a “cluster tool architecture” system. Airlock 830, also known as a loadlock or transfer module, is shown in VTM 838 with four processing modules 820a-820d, which may be individual optimized to perform various fabrication processes. By way of example, processing modules 820a-820d may be implemented to perform substrate etching, deposition, ion implantation, wafer cleaning, sputtering, and/or other semiconductor processes. In some embodiments, ALE and selective deposition are performed in the same module. In some embodiments, ALE and selective deposition are performed in different modules of the same tool. One or more of the substrate etching processing modules (any of 820a-820d) may be implemented as disclosed herein, i.e., for performing ALE, selectively depositing carbon-containing material, and other suitable functions in accordance with the disclosed embodiments. Airlock 830 and process module 820 may be referred to as “stations.” Each station has a facet 836 that interfaces the station to VTM 838. Inside each facet, sensors 1-18 are used to detect the passing of wafer 826 when moved between respective stations.

Robot 822 transfers wafer 826 between stations. In one embodiment, robot 822 has one arm, and in another embodiment, robot 822 has two arms, where each arm has an end effector 824 to pick wafers such as wafer 826 for transport. Front-end robot 832, in atmospheric transfer module (ATM) 840, is used to transfer wafers 826 from cassette or Front Opening Unified Pod (FOUP) 834 in Load Port Module (LPM) 742 to airlock 830. Module center 828 inside process module 820 is one location for placing wafer 826. Aligner 844 in ATM 840 is used to align wafers.

In an exemplary processing method, a wafer is placed in one of the FOUPs 834 in the LPM 842. Front-end robot 832 transfers the wafer from the FOUP 834 to an aligner 844, which allows the wafer 826 to be properly centered before it is etched or processed. After being aligned, the wafer 826 is moved by the front-end robot 832 into an airlock 830. Because airlock modules have the ability to match the environment between an ATM and a VTM, the wafer 826 is able to move between the two pressure environments without being damaged. From the airlock module 830, the wafer 826 is moved by robot 822 through VTM 838 and into one of the process modules 820a-820d. In order to achieve this wafer movement, the robot 822 uses end effectors 824 on each of its arms. Once the wafer 826 has been processed, it is moved by robot 822 from the process modules 820a-820d to an airlock module 830. From here, the wafer 826 may be moved by the front-end robot 832 to one of the FOUPs 834 or to the aligner 844.

It should be noted that the computer controlling the wafer movement can be local to the cluster architecture, or can be located external to the cluster architecture in the manufacturing floor, or in a remote location and connected to the cluster architecture via a network. A controller as described above with respect to FIG. 7 may be implemented with the tool in FIG. 8.

### CONCLUSION

Although the foregoing embodiments have been described in some detail for purposes of clarity of understanding, it will be apparent that certain changes and modifications may be practiced within the scope of the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of processing a metal oxide film, the method comprising:
(a) exposing the metal oxide film to a boron halide reactant and igniting a first plasma with a first bias to modify a surface of the metal oxide film;
(b) exposing the modified surface of the metal oxide film to a second plasma at a second bias and for a duration sufficient to remove the modified surface without sputtering; and
(c) selectively depositing a metal oxide material on the metal oxide film to fill crevices within the metal oxide film.

2. The method of claim 1, wherein the metal oxide film is smoothened.

3. The method of claim 2, wherein the smoothened metal oxide film is used as a mask to etch a carbon-based substrate positioned beneath the metal oxide film resulting in improved local critical dimensions (LCD) of features etched in the carbon-based substrate.

4. The method of claim 1, wherein (a) and (b) comprise an atomic layer etch (ALE) process.

5. The method of claim 2, wherein (c) comprises an atomic layer deposition (ALD) process.

6. The method of claim 5, wherein (a) and (b) comprise an atomic layer etch (ALE) process, and further wherein the ALE and the ALD processes are both selective to carbon-containing materials positioned beneath the metal oxide film.

7. The method of claim 6, wherein the metal oxide film is smoothened without damaging the carbon-containing materials.

8. The method of claim 1, wherein the boron halide reactant is boron trichloride gas (BCl₃).

9. The method of claim 1, wherein the second plasma is generated from chlorine gas (Cl₂).

10. The method of claim 1, wherein the second plasma is generated from an argon-containing gas.

11. The method of claim 1, wherein the first plasma is generated using a plasma power between about 300 W and about 900 W.

12. The method of claim 5, wherein the first bias is 0V and applied for 5 seconds.

13. The method of claim 1, wherein the metal oxide film is zirconium oxide (ZrO₂) film.

14. The method of claim 1, wherein the metal oxide film is aluminum oxide (Al₂O₃) film.

15. The method of claim 14, wherein the modified surface of the aluminum oxide (Al₂O₃) film is exposed to the second plasma that is generated from an argon-containing gas.

16. The method of claim 13, wherein the metal oxide material is zirconium oxide (ZrO₂).

17. The method of claim 16, wherein the zirconium oxide (ZrO₂) is deposited by ALD using thermal half reaction of a zirconium precursor selected from a group consisting of: a zirconium amide, a zirconium halide, or a zirconium alkoxide, and an oxygen-containing precursor selected from a group consisting of: water, alcohol, ozone, or oxygen gas.

18. The method of claim 17, wherein a 1 second dose of zirconium amide provided at partial pressure of 10 mTorr reacted with water is sufficient to achieve a saturated thickness of 1 Å per ALD cycle.

19. The method of claim 17, wherein the temperature at which deposition is conducted is dependent on thermal stability of the zirconium amide.

20. The method of claim 17, wherein the deposition of the zirconium oxide (ZrO₂) by ALD is selective relative to carbon-containing materials positioned beneath the metal oxide film, and further wherein the an oxygen-containing precursor does not oxidize the carbon-containing materials.

21. The method of claim 14, wherein the metal oxide material is aluminum oxide (Al₂O₃).

22. The method of claim 21, wherein the aluminum oxide (Al₂O₃) is deposited by ALD using thermal half reaction of an aluminum precursor selected from a group consisting of: an aluminum amide, an aluminum halide, an aluminum alkoxide, or an aluminum alkyl, and an oxygen-containing precursor selected from a group consisting of: water, alcohol, ozone, or oxygen gas.

23. The method of claim 22, wherein the aluminum alkyl is trimethylaluminum.

24. An apparatus for processing a substrate, the apparatus comprising:
(a) one or more process chambers, each process chamber comprising a chuck;
one or more gas inlets into the process chambers and associated flow-control hardware; and
(b) a controller having at least one processor and a memory, wherein
the at least one processor and the memory are communicatively connected with one another,
the at least one processor is at least operatively connected with the flow-control hardware, and
the memory stores computer-executable instructions for controlling the at least one processor to at least control the flow-control hardware by:
(i) exposing a metal oxide film to a boron halide reactant and igniting a first plasma with a first bias to modify a surface of the metal oxide film;
(ii) exposing the modified surface of the metal oxide film to a second plasma at a second bias and for a duration sufficient to remove the modified surface without sputtering; and
(iii) selectively depositing a metal oxide material on the metal oxide film to fill crevices on the metal oxide film.
